(19) United States
(12) Patent Application Publication
(10) Pub. No.: US 2023/0197635 A1
(43) Pub. Date: Jun. 22, 2023

(54) STIFFENER RING FOR PACKAGES WITH MICRO-CABLE/OPTICAL CONNECTORS

(71) Applicant: Marvell Asia Pte Ltd., Singapore (SG)

(72) Inventors: Janak PATEL, South Burlington, VT (US); Richard S. GRAF, Gray, ME (US); Manish NAYINI, Wappingers Falls, NY (US)

(21) Appl. No.: 18/086,144

(22) Filed: Dec. 21, 2022

Related U.S. Application Data
(60) Provisional application No. 63/292,710, filed on Dec. 22, 2021.

(51) Int. Cl. H01L 23/00; H01L 23/498; H01L 21/48

(52) U.S. Cl. CPC H01L 23/562; H01L 23/49822; H01L 21/4871

(57) ABSTRACT

A semiconductor package includes a package substrate, a semiconductor chip disposed on the package substrate, and a stiffener disposed on the package substrate. The stiffener includes an inner portion configured to surround the semiconductor chip, the inner portion defining a space on the package substrate external to the inner portion and located between the inner portion and outer edges of the package substrate, and a plurality of leg portions extending outwardly from the inner portion toward one or more of the outer edges of the package substrate and corners of the package substrate.

### CROSS-REFERENCE TO RELATED APPLICATIONS

This application claims the benefit of U.S. Provisional Application No. 63/292,710, filed on Dec. 22, 2021. The entire disclosure of the application referenced above is incorporated herein by reference.

### FIELD

The present disclosure relates to stiffeners for semiconductor packages.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor packages (e.g., packages such as individual semiconductor chips or dies, integrated circuit (IC) packages, etc.) typically include one or more circuits formed on a substrate. Various signals are transmitted between components above and/or through the substrate (e.g., through vias formed within the substrate). One or more semiconductor packages may be arranged on a printed circuit board (PCB) or other suitable substrate. In some examples, the semiconductor packages are coupled to the PCB using a ball grid array (BGA).

### SUMMARY

A semiconductor package includes a package substrate, a semiconductor chip disposed on the package substrate, and a stiffener disposed on the package substrate. The stiffener includes an inner portion configured to surround the semiconductor chip, the inner portion defining a space on the package substrate external to the inner portion and located between the inner portion and outer edges of the package substrate, and a plurality of leg portions extending outwardly from the inner portion toward one or more of the outer edges of the package substrate and corners of the package substrate.

In other features, the package substrate is a laminate substrate and the stiffener is comprised of a material having a rigidity greater than the laminate substrate. The stiffener is comprised of metal. The plurality of leg portions includes diagonal leg portions extending from corners of the inner portion toward the corners of the package substrate. The plurality of leg portions includes lateral leg portions extending from sides of the inner portion toward the outer edges of the package substrate. The inner portion is rectangular.

In other features, the semiconductor package further includes a circuit component arranged on the package substrate in the space defined between the inner portion and the outer edges of the package substrate. The circuit component is one of a cable connector and a silicon photonics package. The semiconductor package is a SerDes device.

In other features, an electronic data communications device includes a printed circuit board and the semiconductor package mounted on the printed circuit board. The semiconductor package includes an array of electrical contact terminals and is surface mounted to the printed circuit board to establish a plurality of electrical contacts via the array of electrical contact terminals. The electronic data communications device further includes a second semiconductor package including a second package substrate, a second semiconductor chip arranged on the second package substrate, and a second stiffener disposed on the second package substrate, the second stiffener including a second inner portion configured to surround the second semiconductor chip, the second inner portion defining a second space on the second package substrate external to the second inner portion and located between the second inner portion and outer edges of the second package substrate, and a second plurality of leg portions extending outwardly from the second inner portion toward one or more of the outer edges of the second package substrate and corners of the second package substrate.

In other features, the electronic data communications device further includes a first cable connector disposed on the package substrate in the space defined between the inner portion and the outer edges of the package substrate, a second cable connector disposed on the second package substrate in the space defined between the second inner portion and the outer edges of the second package substrate, and a cable coupling the first cable connector to the second cable connector.

A method of assembling an electronic device includes providing a package substrate and attaching a stiffener to the package substrate, the stiffener including an inner portion configured to surround a semiconductor chip disposed on the package substrate, the inner portion defining a space on the package substrate external to the inner portion and located between the inner portion and outer edges of the package substrate, and a plurality of leg portions extending outwardly from the inner portion toward one or more of the outer edges of the package substrate and corners of the package substrate.

In other features, the method further includes attaching the semiconductor chip to the package substrate within the inner portion. The method further includes attaching a circuit component to the package substrate in the space defined between the inner portion and the outer edges of the package substrate. Attaching the circuit component includes attaching one of a cable connector and a silicon photonics package to the package substrate in the space defined between the inner portion and the outer edges of the package substrate. The method further includes attaching the electronic device to a printed circuit board. Attaching the electronic device to the printed circuit board includes attaching the electronic device to an array of electrical contact terminals. The method further includes attaching the stiffener to the package substrate using an epoxy.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF DRAWINGS

FIG. 1 is a plan (top-down) view of a semiconductor package including a stiffener according to the present disclosure;

FIG. 2A is a side view of semiconductor packages according to the present disclosure arranged on a printed circuit board;

FIG. 2B is a plan view of one of the semiconductor packages of FIG. 2A;

FIGS. 3A, 3B, and 3C are plan views of other example stiffeners according to the present disclosure;

FIG. 4 illustrates steps of an example method of manufacturing or assembling a device including a stiffener according to the present disclosure; and

FIG. 5 illustrates an example manufacturing process for a semiconductor device including a stiffener according to the present disclosure.

In the drawings, reference numbers may be reused to identify similar and/or identical elements.

### DESCRIPTION

Semiconductor packages may include a lid or stiffener (e.g., a stiffener ring) arranged on a package substrate around one or more semiconductor chips. The stiffener is configured to maintain a flatness of the package substrate and semiconductor package. For example, the stiffener prevents warping or warpage. The stiffener may be comprised of stainless steel, copper (e.g., nickel-plated copper), or other suitable material (e.g., other metals) having greater rigidity and resistance to warping than a material of the package substrate (e.g., an organic or other laminate substrate). Accordingly, a footprint of the package substrate may be larger than a footprint of the semiconductor chip in order to accommodate the stiffener on the package substrate. For example, a width of one peripheral side (i.e., a distance from an inner edge to an outer edge) of the stiffener may be 10% or more of the overall width of the package substrate.

In some examples, it may be advantageous to arrange additional components (e.g., circuit components) on the package substrate (e.g., instead of being arranged on the PCB or in a different semiconductor package on the PCB). For example, the semiconductor chip may communicate with another component (e.g., a cable connecter) arranged on the PCB. Accordingly, signals are transmitted from the chip through the package substrate, a ball grid array (BGA) coupling the package substrate to the PCB, and through the PCB to the other component. In other examples, the package substrate is coupled to the PCB using other types of connections (e.g., other types of arrays of electrical contact terminals), including, but not limited to, other contact grid arrays such as land grid arrays (LGAs), pin grid arrays (PGAs), etc. When contact grid arrays such as BGAs, PGAs, and PGAs are used for mounting semiconductor chips to package substrates and package substrates to PCBs, warpage may make it difficult or even impossible to maintain sufficient electrical contact between all contact points in the contact grid arrays. As pitch decreases, the negative effects of warpage increase.

As one example, a transmission path from the semiconductor chip to other components on the PCB through the BGA has an associated signal loss. As signal transmission rates increase for some applications (e.g., for 200G or greater serializer/de-serializer (SerDes) devices), signal integrity requirements also increase. Accordingly, the signal loss associated with transmission from the semiconductor chip to an associated cable connector arranged on the PCB via the BGA may not meet signal integrity requirements. In other words, the signal loss may exceed a maximum signal loss for 200G SerDes applications.

Conversely, arranging the cable connector on the same substrate as the semiconductor chip would decrease the length of the transmission path and significantly decrease loss associated with transmission of the signals to the cable connector. However, the footprint of the package substrate would need to be increased significantly to accommodate such a cable connector. Further, placement of the cable connector is constrained by the position of the stiffener. Typically, the stiffener is arranged at the outermost perimeter of the package substrate to maintain the flatness at the outermost edges of the semiconductor package. Accordingly, in order to accommodate disposition of the cable connector between the stiffener and the semiconductor chip in a conventional arrangement, the footprint of the package substrate would need to be increased, which would increase the likelihood of warpage. Conversely, by extending the perimeter of the package substrate beyond the stiffener (i.e., to accommodate additional components in a region of the package substrate outside of the stiffener) the likelihood of warpage at the outermost edges would be increased.

A semiconductor package and stiffener assembly according to the present disclosure thus is configured to increase space available on the package substrate for components such as a cable connector while also maintaining flatness and minimizing the likelihood of warpage. For example, in an embodiment the stiffener includes an inner portion, or ring, disposed on the package substrate around (e.g., directly adjacent to or within 0-6 mm of) the semiconductor chip or die and one or more leg portions extending radially outwardly from the inner portion. For example, the leg portions may extend diagonally outwardly from corners of the inner portion toward respective corners of the package substrate. Although described herein as a “ring,” the inner portion may have a generally rectangular, square, or other shape suitable to surround one or more semiconductor chips arranged on the package substrate.

In this manner, the stiffener according to the present disclosure maintains the flatness of the package substrate and prevents its warping while also providing space for components to be arranged on the package substrate outside of the inner portion (e.g., between the inner portion and the outer edge of the package substrate).

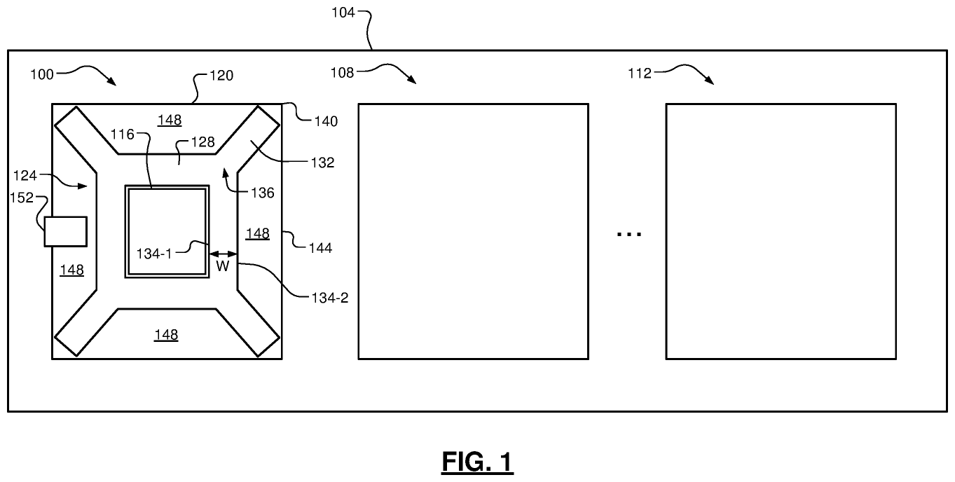

FIG. 1 shows a plan (top-down) view of a semiconductor package 100 according to the present disclosure arranged on a PCB 104. One or more additional semiconductor packages (108, 112, etc.) may be arranged on the PCB 104. The other semiconductor packages 108, 112, may have a same or different configuration relative to the semiconductor package 100. For example, the other semiconductor packages 108, 112 may include, but are not limited to, SerDes devices, Cu wire and optical PHY devices, Ethernet switch devices, automotive PHY devices, storage devices, network and other processors, etc. The semiconductor package 100 includes a semiconductor die or chip 116 arranged on a substrate such as package substrate 120. By way of example only, the semiconductor chip 116 comprises a 20 mm×20 mm die and the package substrate 120 is 55×55 mm. Various other suitable sizes are contemplated.

A stiffener 124 is disposed on the package substrate 120. In some embodiments, the stiffener 124 is attached to the package substrate 120 with an epoxy such as EA6700, SE4450, Sylgard 577 etc. and cured at high temperature (e.g., 150 degrees Celsius or greater for up to 3 hours). The stiffener 124 includes an inner portion 128 (e.g., a ring) and one or more leg portions 132. The inner portion 128 surrounds the semiconductor chip 116. While shown as generally rectangular or square shaped, the inner portion 128 may have other suitable shapes. In an embodiment, the inner portion 128 is directly adjacent to or within 0-6 mm of the semiconductor chip 116. The stiffener 124 may be comprised of stainless steel, copper (e.g., nickel-plated copper), or other suitable stiffener material having rigidity and resistance to warping greater than a material of the package substrate 120. For example, the package substrate 120 is an organic or other type of laminate substrate.

A width W of one peripheral side of the stiffener 124 (i.e., a distance from an inner edge 134-1 to an outer edge 134-2) may be 10% or more of the overall width of the package substrate 120, in an embodiment. For example, the width W may be 2.0-6.0 mm. The width W may be the same or may vary for different portions of the stiffener 124 (e.g., the leg portions 132 may wider or narrow than the sides of the inner portion 128). A thickness (e.g., a height) of the stiffener 124 may be 0.5 mm to 4.0 mm. The thickness may vary for different portions of the stiffener 124 (e.g., the leg portions 132 may be thicker or thinner than the sides of the inner portion 128).

As shown, the leg portions 132 extend radially outward from the inner portion 128. For example, the leg portions 132 extend diagonally outward from corners 136 of the inner portion 128 toward respective corners 140 of the package substrate. Although four of the leg portions 132 are shown, in other examples the stiffener 124 may include fewer or more of the leg portions 132 in different configurations. Additional example configurations are described below in more detail. Although shown as being generally rectangular (e.g., with squared-off ends), in other examples the leg portions 132 may have other shapes (e.g., tapered or rounded ends, a curved or “S” shape, a piece-wise linear shape having one or more angled bends, etc.). The leg portions 132 may each have the same size (e.g., width and length) as shown or may have different sizes.

The stiffener 124 according to the present disclosure is configured to increase space available on the package substrate 120 for additional components to be disposed on the package substrate outside of the inner portion 128 (i.e., on a side of the inner portion 128 opposite the semiconductor chip 116) while also maintaining flatness and minimizing likelihood of the package substrate 120 becoming warped. For example, a footprint of the package substrate 120 is increased relative to the semiconductor chip 116 such that a perimeter or outer edge 144 of the package substrate 120 extends beyond the inner portion 128 of the stiffener 124 but retains the structural rigidity provided by the leg portions 132. Accordingly, space for additional components on the package substrate 120 is defined in outer regions 148 of the package substrate 120 external to the inner portion 128 (i.e., between the inner portion 128 and the outer edge 144 and between adjacent ones of the leg portions 132).

The leg portions 132 extending to the outer edge 144 provide additional rigidity and structural support to the package substrate 120 to maintain flatness and prevent warping of the package substrate 120. In this manner, the inner portion 128 is shifted inward toward the semiconductor chip 116 to provide space for additional components without compromising flatness of the package substrate 120. Further, the position of the inner portion 128 inward of the outer edge 144 provides access to the outer edge 144 and components arranged on the package substrate 120 external to the inner portion 128.

As one example, a cable connector 152 (e.g., a twin-axial micro-cable connector) may be surface mounted or edge mounted on the package substrate proximate to or overlapping the outer edge 144 as described below in more detail. Since the cable connector 152 is positioned externally to the inner portion 128 (i.e., nearer to the outer edge 144 than the inner portion 128 is to the outer edge 144), the cable connector 152 can be readily accessed to connect or disconnect a cable. Other example components that may be located on the package substrate 120 external to the inner portion 128 include, but are not limited to, a silicon photonics package, co-packaged optics (CPOs), capacitors or capacitor arrays, etc.

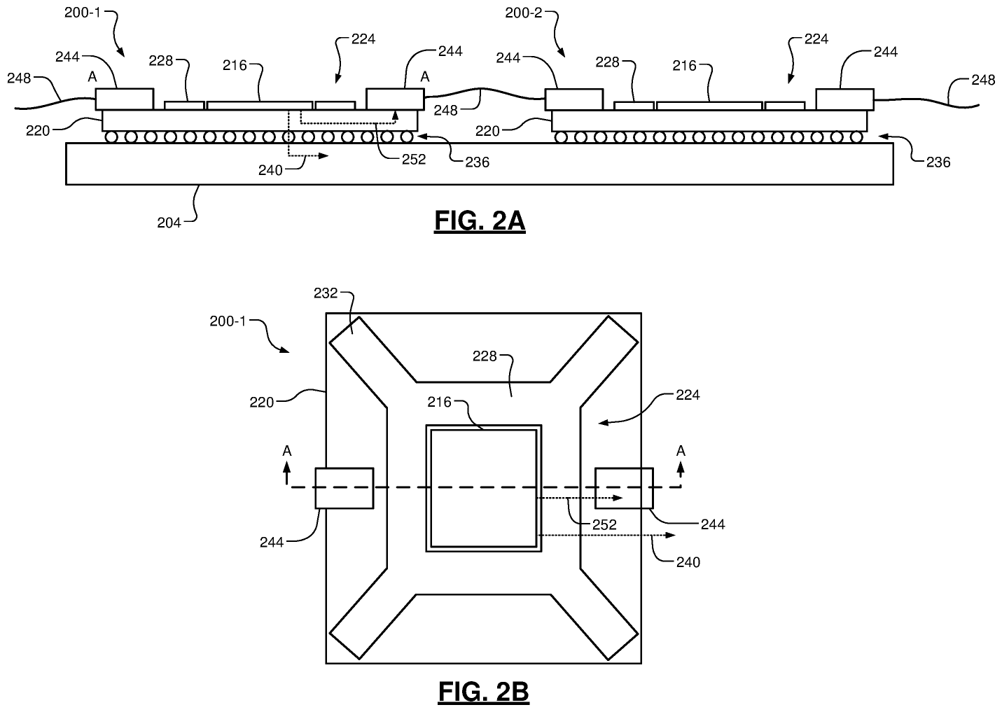

FIG. 2A shows a side view of semiconductor packages 200-1 and 200-2 (collectively, semiconductor packages 200) arranged on a PCB 204. The semiconductor package 200-1 as shown in FIG. 2A is a cross-sectional view taken along a line A shown in FIG. 2B. The semiconductor packages 200 each include a semiconductor die or chip 216 arranged on a package substrate 220. A stiffener 224 according to the present disclosure is arranged on the package substrate 220. The stiffener 224 includes an inner portion 228 and leg portions 232 similar to those described above in FIG. 1. The leg portions 232 are not visible in the view shown in FIG. 2A.

In some examples, the semiconductor chips 216 transmit signals to other semiconductor chips or components arranged on the PCB 204 via the package substrate 220, a BGA 236 coupling the package substrate 220 to the PCB 204. An example transmission or signal path from the semiconductor chip 216 of the semiconductor package 200-1 is shown at 240. In some examples, signals are transmitted through a BGA (or other connections types, such as other contact grid arrays as described above) to connectors arranged on the PCB 204, which has an associated signal loss.

As shown in FIGS. 2A and 2B, the stiffeners 224 according to the present disclosure are configured to increase space available on the package substrates 220 for components to be arranged outside of the inner portions 228 while also maintaining flatness of the package substrate and minimizing likelihood of warping of the package substrates 220. For example, by reducing the likelihood of warpage, connectors 244 may be mounted on the package substrates 220, rather than being mounted on the PCB 204, thereby achieving improved connectivity (e.g., facilitating greater data transfer rates and/or bandwidth) between the semiconductor chips and other components which can now be co-packaged. In one example, the semiconductor package 200-1 is a 200G or greater SerDes device and the connectors 244 are configured to transmit SerDes signals to and from the semiconductor package 200-1 (e.g., via respective cables 248). For example, the cables 248 couple respective connectors 244 of the semiconductor packages 200 together for transmission of signals between the semiconductor packages 200, to other components of the PCB 204 and/or external to the PCB 204, etc.

An example signal path 252 (e.g., a signal trace) from the semiconductor chip 216 to one of the connectors 244 arranged on the substrate 220 is shown. The signal path 252 passes only through the package substrate 220 (i.e., rather than passing through the BGA 236, the PCB 204, etc.), which typically has an improved signal carrying characteristics in comparison to a PCB, but by the same token is also susceptible to warpage. Accordingly, a length of the signal 252 path is decreased (i.e., relative to a signal path from the semiconductor chip 216 and a component arranged on the PCB 204) and loss associated with transmission of signals from the semiconductor chip 216 and the connector 244 decreases.

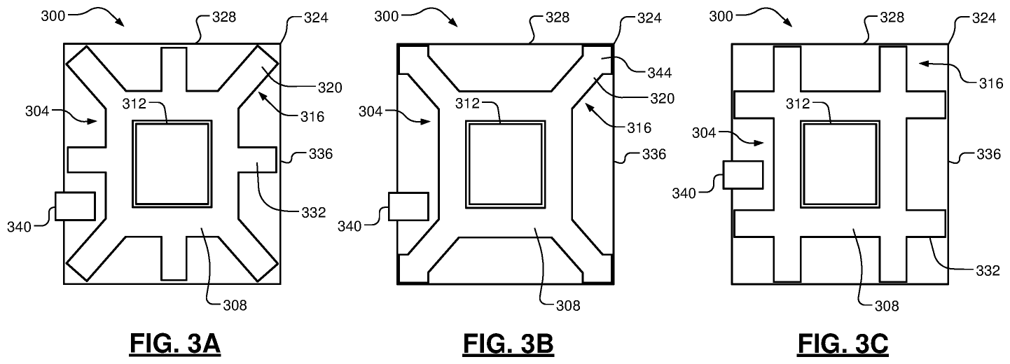

FIGS. 3A, 3B, and 3C show other examples of a semiconductor package 300 including a stiffener 304 according to the present disclosure. In FIG. 3A, the stiffener 304 includes an inner portion 308 surrounding a semiconductor chip 312 and a plurality of leg portions 316. In this example, the leg portions 316 include diagonal leg portions 320 extending diagonally from the inner portion 308 to respective corners 324 of a substrate 328 and lateral leg portions 332 extending laterally from sides of the inner portion 308 to outer edges 336 of the package substrate 328. As shown, the lateral leg portions 332 extend from respective centers of each side of the inner portion 308. The lateral leg portions 332 extend in a direction perpendicular to a respective one of the outer edges 336. The lateral leg portions 332 provide additional rigidity and prevention of warping of the package substrate 328 (i.e., relative to examples having only the diagonal leg portions 320). Further, space is provided on the package substrate 328 between the inner portion 308 and the outer edges 336 to accommodate additional components, such as a connector 340.

In the example shown in FIG. 3B, the leg portions 316 include the diagonal leg portions 320 and rectangular foot portions 344 arranged at respective ends of the diagonal leg portions 320. The rectangular foot portions 344 are arranged in the respective corners 324 of the package substrate 328.

In the example shown in FIG. 3C, the leg portions 316 include only the lateral leg portions 332 (i.e., the leg portions 316 do not include the diagonal leg portions 320 as shown in FIGS. 3B and 3C. The lateral leg portions 332 may extend from corner regions of the inner portion 308 in a direction perpendicular to respective outer edges 336 of the package substrate, as shown, and/or from respective centers of each side of the inner portion 308 as shown in FIG. 3A.

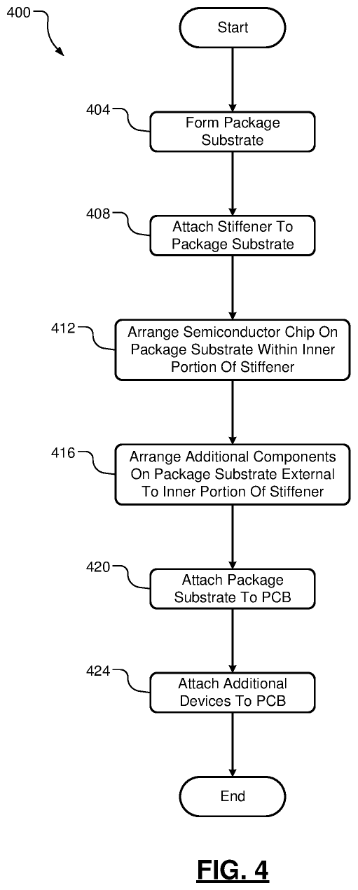

FIG. 4 illustrates steps of an example method 400 of manufacturing or assembling an electronic device (e.g., an electronic data communications device) including a stiffener according to the present disclosure. At 404, a package substrate is provided. For example, the package substrate is formed using one or more semiconductor materials, such as silicon. At 408, a stiffener according to the present disclosure is attached to the package substrate. For example, the stiffener is attached to the package substrate using an epoxy and cured as described above. At 412, a semiconductor device or chip is arranged on the package substrate within a perimeter defined by the stiffener. The stiffener includes an inner ring portion surrounding the semiconductor chip and one or more leg portions extending from the inner ring portion toward outer edges of the package substrate. At 416, one or more additional components (e.g., a connector) are optionally arranged on the package substrate external to the inner ring portion. At 420, the package substrate is attached to a PCB (e.g., via a contact grid array such as a BGA). For example, the contact grid array is formed on the PCB and the package substrate is attached to the contact grid array. At 424 one or more additional semiconductor devices and package substrates are optionally attached to the PCB.

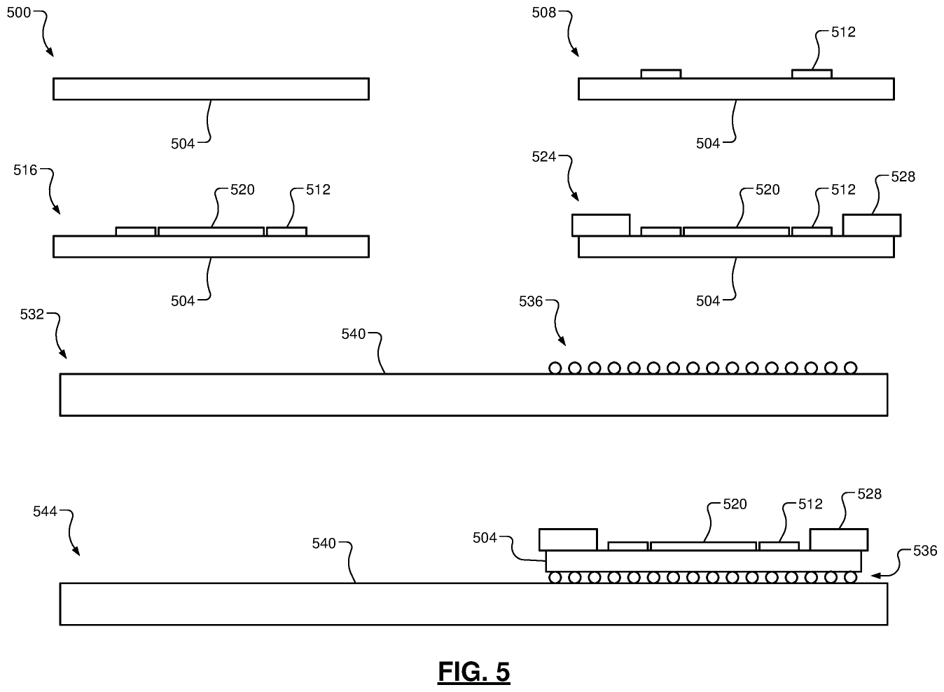

FIG. 5 illustrates an example manufacturing/assembly process for an electronic device including a stiffener according to the present disclosure. At 500, a package substrate 504 is shown. At 508, a stiffener 512 according to the present disclosure is attached to the package substrate 504. For example only, the stiffener 512 is attached using epoxy, which is then cured as described above. Although described as being attached to the package substrate 504 prior to any other components, in other examples the stiffener 512 may be attached to the package substrate 504 subsequent to other components.

At 516, a semiconductor chip 520 is attached to the package substrate 504 within an inner portion of the stiffener 512. At 524, one or more additional components (e.g., a cable connector 528 as described above) is arranged on the package substrate 504 external to an inner portion of the stiffener 512. At 532, a contact grid array such as a BGA 536 is formed on a PCB 540. At 544, the package substrate 504 is attached to the PCB 540 via the BGA 536.

In other examples, the components of the semiconductor device may be assembled in a sequence different than that described above. For example, the package substrate 504 may be attached to the PCB 540 prior to attaching the semiconductor chip 520 and/or the stiffener 512.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms. Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. A semiconductor package, comprising:
a package substrate;
a semiconductor chip disposed on the package substrate; and
a stiffener disposed on the package substrate, the stiffener comprising
an inner portion configured to surround the semiconductor chip, the inner portion defining a space on the package substrate external to the inner portion and located between the inner portion and outer edges of the package substrate, and
a plurality of leg portions extending outwardly from the inner portion toward one or more of (i) the outer edges of the package substrate and (ii) corners of the package substrate.

2. The semiconductor package of claim 1, wherein the package substrate is a laminate substrate and the stiffener is comprised of a material having a rigidity greater than the laminate substrate.

3. The semiconductor package of claim 2, wherein the stiffener is comprised of metal.

4. The semiconductor package of claim 1, wherein the plurality of leg portions includes diagonal leg portions extending from corners of the inner portion toward the corners of the package substrate.

5. The semiconductor package of claim 1, wherein the plurality of leg portions includes lateral leg portions extending from sides of the inner portion toward the outer edges of the package substrate.

6. The semiconductor package of claim 1, wherein the inner portion is rectangular.

7. The semiconductor package of claim 1, further comprising a circuit component arranged on the package substrate in the space defined between the inner portion and the outer edges of the package substrate.

8. The semiconductor package of claim 7, wherein the circuit component is one of a cable connector and a silicon photonics package.

9. The semiconductor package of claim 1, wherein the semiconductor package is a SerDes device.

10. An electronic data communications device comprising a printed circuit board and the semiconductor package of claim 1 mounted on the printed circuit board.

11. The electronic data communications device of claim 10, wherein the semiconductor package includes an array of electrical contact terminals and is surface mounted to the printed circuit board to establish a plurality of electrical contacts via the array of electrical contact terminals.

12. The electronic data communications device of claim 10, further comprising a second semiconductor package, the second semiconductor package comprising:
a second package substrate;
a second semiconductor chip arranged on the second package substrate; and
a second stiffener disposed on the second package substrate, the second stiffener comprising
a second inner portion configured to surround the second semiconductor chip, the second inner portion defining a second space on the second package substrate external to the second inner portion and located between the second inner portion and outer edges of the second package substrate; and
a second plurality of leg portions extending outwardly from the second inner portion toward one or more of (i) the outer edges of the second package substrate and (ii) corners of the second package substrate.

13. The electronic data communications device of claim 12, further comprising:
a first cable connector disposed on the package substrate in the space defined between the inner portion and the outer edges of the package substrate;
a second cable connector disposed on the second package substrate in the space defined between the second inner portion and the outer edges of the second package substrate; and
a cable coupling the first cable connector to the second cable connector.

14. A method of assembling an electronic device, the method comprising:
providing a package substrate; and
attaching a stiffener to the package substrate, the stiffener comprising
an inner portion configured to surround a semiconductor chip disposed on the package substrate, the inner portion defining a space on the package substrate external to the inner portion and located between the inner portion and outer edges of the package substrate, and
a plurality of leg portions extending outwardly from the inner portion toward one or more of (i) the outer edges of the package substrate and (ii) corners of the package substrate.

15. The method of claim 14, further comprising attaching the semiconductor chip to the package substrate within the inner portion.

16. The method of claim 15, further comprising attaching a circuit component to the package substrate in the space defined between the inner portion and the outer edges of the package substrate.

17. The method of claim 16, wherein attaching the circuit component includes attaching one of a cable connector and a silicon photonics package to the package substrate in the space defined between the inner portion and the outer edges of the package substrate.

18. The method of claim 14, further comprising attaching the electronic device to a printed circuit board.

19. The method of claim 18, wherein attaching the electronic device to the printed circuit board includes attaching the electronic device to an array of electrical contact terminals.

20. The method of claim 14, further comprising attaching the stiffener to the package substrate using an epoxy.
